(19) United States
(12) Patent Application Publication
(10) Pub. No.: US 2018/0168351 A1
(43) Pub. Date: Jun. 21, 2018

(54) PANEL FOR HOME APPLIANCE AND HOME APPLIANCE INCLUDING THE SAME

(71) Applicant: Samsung Electronics Co., Ltd., Suwon-si (KR)

(72) Inventors: Cheol Hee CHO, Gunpo-si (KR); Young Deog KOH, Seongnam-si (KR)

(21) Appl. No.: 15/838,715

(22) Filed: Dec. 12, 2017

(30) Foreign Application Priority Data
Dec. 19, 2016 (KR) 10-2016-0173402

(51) Int. Cl. A47B 96/20; C23C 14/22; F24C 15/06

(52) U.S. Cl. CPC A47B 96/20; F25D 23/06; F24C 15/06; C23C 14/22

(57) ABSTRACT

Disclosed herein are a panel for a home appliance which may provide aesthetics and a home appliance including the same. The panel for a home appliance is provided to form an exterior of the home appliance, and the panel for a home appliance may include a base material layer, a patterer layer formed on the base material layer, a color layer disposed on the pattern layer to develop a color, a coupling layer applied on the pattern layer to couple the base material layer and the color layer, and a protective layer disposed on the color layer such that contaminations easily removed therefrom.

### CROSS-REFERENCE TO RELATED APPLICATIONS AND CLAIM OF PRIORITY

This application is related to and claims priority to Korean Patent Application No. 10-2016-0173402, filed on Dec. 19, 2016, the contents of which are incorporated herein by reference.

### TECHNICAL FIELD

Embodiments of the present disclosure relate to a panel for a home appliance and a home appliance including the same, and more particularly, to a panel for a home appliance configured to provide aesthetics, and a home appliance including the same.

### BACKGROUND

Generally, an exterior of a home appliance, such as a refrigerator, an oven, and a dishwasher, may have various colors in consideration of a design viewpoint.

Methods of developing a color on an exterior of a home appliance may include a chemical coloring method, a vapor deposition method, a painting method, and the like.

The chemical coloring method is not adequate in a viewpoint of productivity because a panel for a home appliance should be immersed in a strong oxidizing solution for a long time to realize a specific color.

A physical vapor deposition (PVD) method, which is mainly used as the vapor deposition method, has been recently developed as a roll to roll method and applied to production of panel for a home appliance, but has a problem in that a yield decreases significantly.

The painting method has a problem in that a pigment dispersant used to develop a color on a panel for a home appliance may decrease transparency of the panel for a home appliance. For example, in a case in which the panel for a home appliance is a metal, the painting method may reduce inherent metallic aesthetics of the panel for a home appliance.

### SUMMARY

To address the above-discussed deficiencies, it is a primary object to provide a panel for a home appliance having an improved structure capable of improving productivity, and a home appliance including the same.

It is another aspect of the present disclosure to provide a panel for a home appliance having a structure capable of realizing high transparency, and a home appliance including the same.

Additional aspects of the disclosure will be set forth in part in the description follows and, in part, will be obvious from the description, or may be learned by practice of the disclosure.

In accordance with one aspect of the present disclosure, a panel for a home appliance provided to form an exterior of a home appliance, the panel for a home appliance includes a base material layer, a pattern layer formed on the base material layer, a color layer disposed on the pattern layer to develop a color, a coupling layer applied on the pattern layer to couple the base material layer and the color layer, and a protective layer disposed on the color layer such that contamination is easily removed therefrom.

The base material layer may include a stainless steel.

The color layer may include a black paint to develop a black color.

The pattern layer may include at least one of a linear pattern, a dot pattern, and an embossing pattern.

The coupling layer may include at least one of an organic-inorganic composite-based material and a zinc phosphate-based material.

The black paint may include a pigment dispersant, wherein 90% or more of the pigment dispersant may have a particle size in a range of 60 nm to 350 nm.

A content of the pigment dispersant may range from 8.0 wt % to 15.0 wt % in 100 wt % of the black paint.

The black paint may further include a resin including at least one of an epoxy resin and an acryl resin, and a content of the resin may range from 30 wt % to 50 wt % in 100 wt % of the black paint.

The protective layer may include at least one of a water-soluble material, an oil-based material, and an organic-inorganic composite-based material including a fluorine-based additive.

A content of the fluorine-based additive may range from 0.1 wt % to 2.0 wt % in 100 wt % of the protective layer.

The protective layer may include at least one of a water-soluble material, an oil-based material, and an organic-inorganic composite-based material including a bead type polymer additive.

A content of the bead type polymer additive may range from 0.1 wt % to 2.0 wt % in 100 wt % of the protective layer.

In accordance with another aspect of the present disclosure, a home appliance includes a main body provided to form an exterior of the home appliance, and a panel for a home appliance configured to form at least one surface of outer surfaces of the main body, wherein the panel for a home appliance includes a base material layer formed of a metal material, a pattern layer formed on the base material layer, a color layer disposed on the pattern layer to develop a color, a coupling layer applied on the pattern layer to couple the base material layer and the color layer, and a protective layer disposed on the color layer such that contamination is easily removed therefrom.

The color layer may include a black paint to develop a black color.

The coupling layer may include at least one of an organic-inorganic composite-based material and a zinc phosphate-based material,

The black paint may include a pigment dispersant, and a resin including at least one of an epoxy resin and an acryl resin, wherein 90% or more of the pigment dispersant has a particle size in a range of 60 nm to 350 nm.

The protective layer may include at least one of a fluorine-based additive and a polymer additive.

In accordance with still another aspect of the present disclosure, a home appliance includes a cabinet, a door rotatably installed at the cabinet and configured to form an exterior of the home appliance together with the cabinet, and a panel for a home appliance provided to form an outer surface of the door, wherein the panel for a home appliance includes a base material layer formed of a metal material, a pattern layer formed on the base material layer, a color layer disposed on the pattern layer to develop a color, a coupling layer applied on the pattern layer to couple the base material layer and the color layer, and a protective layer disposed on the color layer such that contamination is easily removed therefrom and including at least one of a fluorine-based additive and a polymer additive.

Before undertaking the DETAILED DESCRIPTION below; it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings in which like reference numerals represent like parts:

FIG. 1 is a schematic view illustrating a home appliance according to one embodiment of the present disclosure;

FIG. 2 is a schematic view illustrating another home appliance according to one embodiment of the present disclosure;

FIG. 3 is a schematic view illustrating still another one appliance according to one embodiment of the present disclosure;

FIG. 4 is a cross-sectional view illustrating a panel for a home appliance according to one embodiment of the present disclosure;

FIG. 5 is a picture showing a material of a panel for the home appliance of FIG. 1.

FIGS. 6A, 6B and 6C are views illustrating various patterns applicable to a pattern layer of the panel for a home appliance according to one embodiment of the present disclosure;

FIG. 7 is a table showing whether a coupling layer has adhesiveness, corrosion resistance, and process adhesiveness based on a component forming the coupling layer;

FIG. 8 is a graph showing an extent to which a black color is developed on the basis of a particle size of a pigment dispersant forming a color layer; and

FIG. 9 is a table showing whether a protective layer has fingerprint resistance and ease of decontamination based on a kind of additive forming the protective layer.

### DETAILED DESCRIPTION

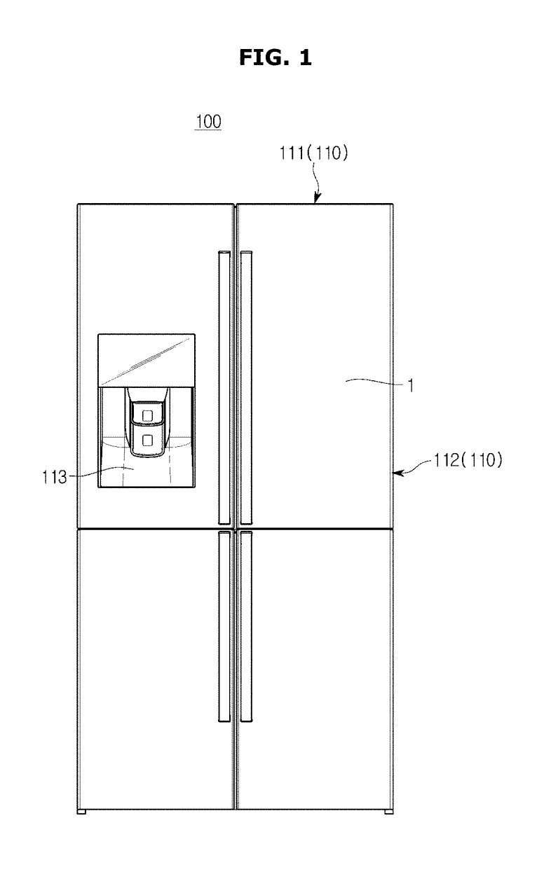

FIGS. 1 through 9, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

Hereinafter, an exemplary embodiment of the present disclosure will be described in detail with reference to the accompanying drawings. Meanwhile, terms used in the specification, such as “front end,” “back end,” “upper portion,” “lower portion,” “upper end,” and “lower end” are defined on the basis of the drawings, and shapes and positions of components are not limited to the terms.

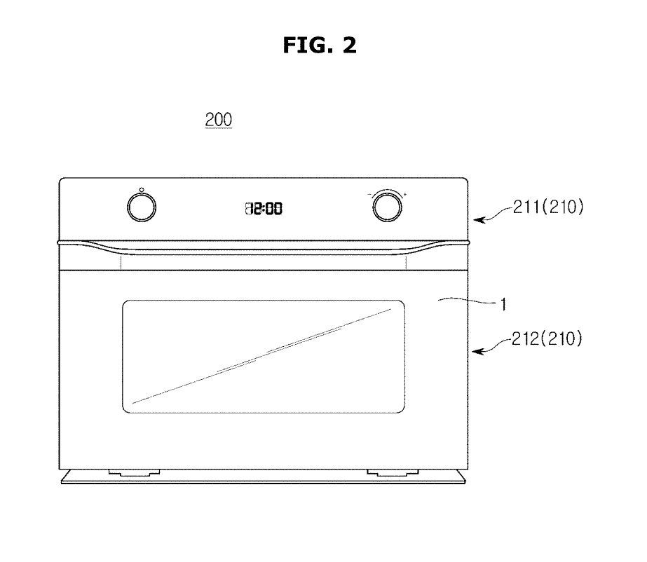

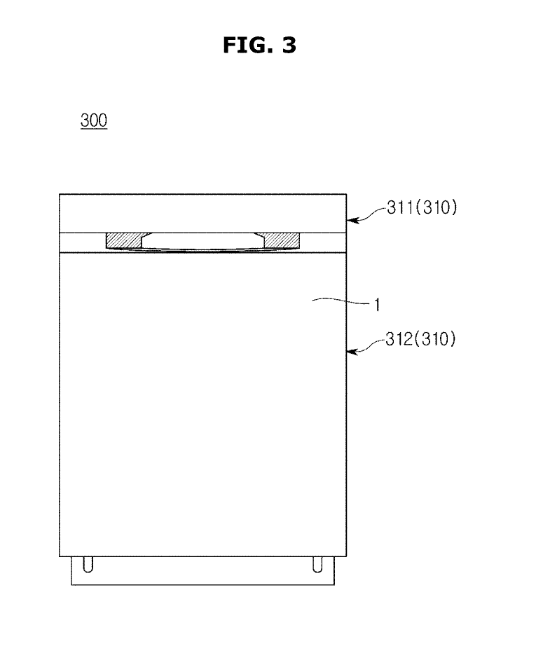

FIG. 1 is one schematic view illustrating a home appliance according to one embodiment of the present disclosure, FIG. 2 is a schematic view illustrating another home appliance according to one embodiment of the present disclosure, and FIG. 3 is a schematic view illustrating still another home appliance according to one embodiment of the present disclosure.

As illustrated in FIG. 1, a panel 1 for a home appliance may be applied to a refrigerator 100 to realize a luxurious and sophisticated appearance thereof. Specifically, the refrigerator 100 may include a main body 110 provided to form an exterior thereof, and the panel 1 for a home appliance may be provided to form at least one surface of outer surfaces of the main body 110. More specifically, the refrigerator 100 may include a cabinet 111 having storage compartments (not shown), and doors 112 rotatably installed at the cabinet 111 to open and close the storage compartments and configured to form the exterior together with the cabinet 111. The doors 112 may form a front exterior of the refrigerator 100. The refrigerator 100 may further include an ice-making compartment (not shown) configured to make ice and store the ice and a dispenser 113 installed at one of the doors 112 to supply ice stored in the ice-making compartment to the outside. The panel 1 for a home appliance may be provided to form at least one of an outer surface of the cabinet 111 and an outer surface of the door 112. Preferably, the panel 1 for a home appliance may be provided to form the outer surface of the door

As illustrated in FIG. 2, a panel 1 for a home appliance may be applied to an oven 200 to realize a luxurious and sophisticated appearance thereof. Specifically, the oven 200 may include a main body 210 provided to form an exterior of the oven 200, and the panel 1 for a home appliance may be provided to form at least one surface of the outer surfaces of the main body 210. More specifically, the oven 200 may include a cabinet 211 having a cooking compartment (not shown) and a door 212 rotatably installed at the cabinet 211 to open and closed the cooking compartment and configured to form the exterior together with the cabinet 211. The door 212 may form a front exterior of the oven 200. The panel 1 for a home appliance may be provided to form at least one of outer surfaces of the door 212 and the cabinet 211. Preferably, the panel 1 for a home appliance may be provided to form the outer surface of the door 212.

As illustrated in FIG. 3, a panel 1 for a home appliance may be applied to a dishwasher 300 to realize curious and sophisticated appearance. Specifically, the dishwasher 300 may include a main body 310 provided to form an exterior of the dishwasher 300, and the panel 1 for a home appliance may be provided to form at least one surface of the outer surfaces of the main body 310. More specifically, the dishwasher 300 may include a cabinet 311 having a washing chamber (not shown), and a door 312 rotatably installed at the cabinet 311 to open and close the washing chamber and configured to form the exterior together with the cabinet 311. The door 312 may form a front exterior of the dishwasher 300. The panel 1 for a home appliance may be provided to form at least one of outer surfaces of the cabinet 311 and the door 312. Preferably, the panel 1 for a home appliance maybe provided to form the outer surface of the door 312.

The panels 1 for the home appliances of the present disclosure may be applied to the refrigerator 100, the oven 200, and the dishwasher 300, as illustrated in FIGS. 1 to 3, and various appliances such as a kimchi refrigerator, an air conditioner, a washing machine, a microwave oven, and a hood. Here, the microwave oven may also include an over the range (OTR) type microwave oven. Consequently, the panel 1 for a home appliance of the present disclosure may be widely applied to exteriors of various home appliances to improve designs of the home appliances.

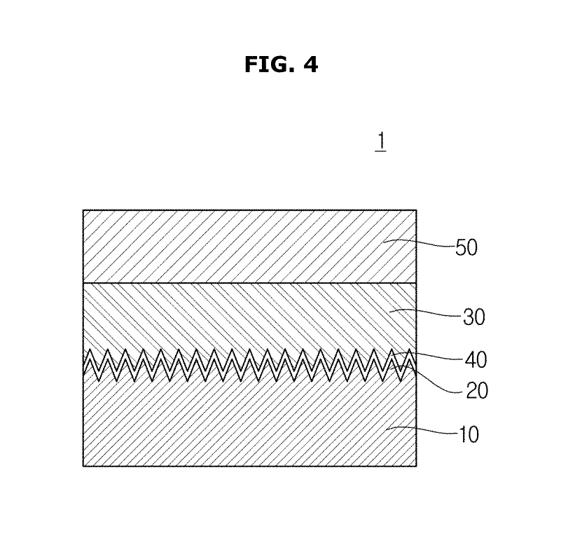

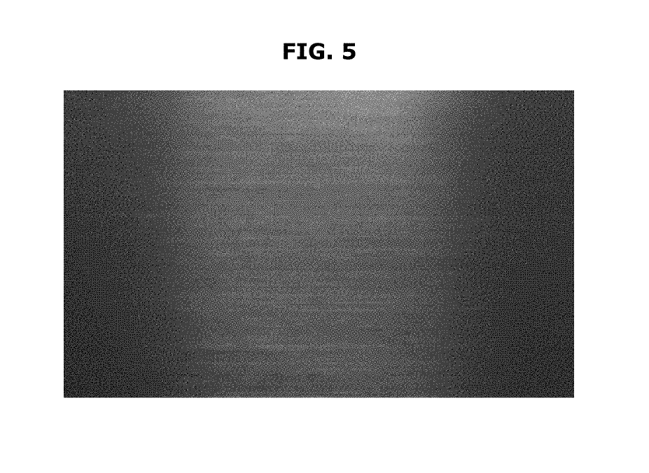

FIG. 4 is a cross-sectional view illustrating a panel for a home appliance according to one embodiment of the present disclosure. A case in which a pattern layer 20 of FIG. 5 is applied to the panel will he mainly described for convenience of describing FIG. 4.

As illustrated in FIG. 4, the panel 1 for a home appliance may include a base material layer 10. The base material layer 10 may include a metal material. Specifically, the base material layer 10 may include a stainless steel. The stainless steel may include at least one of an austenitic stainless steel and a ferritic stainless steel. For example, the austenitic stainless steel may include STS304. For example, the ferritic stainless steel may include STS445NF, STS430J1L, STS430, or the like.

The panel 1 for a home appliance may further include the pattern layer 20 formed on the base material layer 10 The pattern layer 20 may be formed directly on the base material layer 10. Various patterns applicable to the pattern layer 20 will be described below.

The panel 1 for a home appliance may further include a color layer 30 disposed on the pattern layer 20 to develop a color.

The color layer 30 may include a black paint to develop a black color.

The black paint may include a pigment dispersant. The pigment dispersant may include a black pigment dispersant. The pigment dispersant may further include a blue pigment dispersant and a red pigment dispersant configured to perform a tuning function, :In a case in which the blue pigment dispersant is added to the black paint, a blue-tinted black color may be realized. When the red pigment dispersant is added to the black paint, a red-tinted black color may be realized. In a case in the pigment dispersant includes all of the black pigment dispersant, the blue pigment dispersant, and the red pigment dispersant, a content of the black pigment dispersant is the largest, and contents of the blue pigment dispersant and the red pigment dispersant are smaller than that of the black pigment dispersant.

90% or more of the pigment dispersant may have a particle size of 500 nm or less. Preferably, 90% or more of the pigment dispersant may have a particle size in the range of 60 nm to 350 nm.

A content of the pigment dispersant may range from 8.0 wt % to 15.0 wt % in 100 wt % of the black paint.

The black paint may be obtained by dispersing the pigment dispersant a plurality of times using zirconium oxide beads advantageous for dispersing the pigment. Preferably, the black paint may be obtained by dispersing the pigment dispersant two times using the zirconium oxide beads. A pigment dispersant dispersed one time may have a particle size in the range of 1 μm 10 μm. A pigment dispersant dispersed two times may have a particle size in the range of 60 nm to 350 nm.

The black paint may be obtained by dispersing at least one pigment dispersant a plurality of times using the zirconium oxide beads advantageous for dispersing the pigment. Here, the at least one pigment dispersant may include a black pigment dispersant as a base material, and at least one of a blue pigment dispersant and a red pigment dispersant may be added thereto.

The black paint may further include a resin having at least one of an epoxy resin and an acryl resin. The resin may improve color expression of the color layer 30. In addition, the resin may improve durability of the color layer 30.

A content of the resin may range from 30 wt % to 50 wt % in 100 wt % of a black paint.

The panel 1 for a home appliance may further include a coupling layer 40 interposed between the pattern layer d the color layer 30 to couple the base material layer 10 and the color layer 30. Specifically,the coupling layer 40 may be applied to the pattern layer 20 to couple the base material layer 10 and the color layer 30. Preferably, the coupling layer 40 may be applied to the pattern layer 20 at 3.0 g/m² or less.

The coupling layer 40 may firmly couple the base material layer 10 and the color layer 30. Because of the presence of such a coupling layer 40, corrosion resistance of the base material layer 10 may be improved.

The coupling layer 40 may include at least one of an organic-inorganic composite-based material and a zinc phosphate-based material.

The panel I for a home appliance may further include a protective layer 50 disposed on the color layer 30. The protective layer 50 may be formed to have fingerprint resistance. In addition, the protective layer 50 may be formed to be easily decontaminated.

The protective layer 50 may include at least one of a fluorine-based additive and a polymer additive.

Specifically, the protective layer 50 may include at least one of a water-soluble material, an oil-based material, and an organic-inorganic composite-based material including the fluorine-based additive. A content of the fluorine-based additive may range from 0.1 wt % to 2.0 wt % in 100 wt % of the protective layer 50.

Specifically, the protective layer 50 may include at least one of a water-soluble material, an oil-based material, and an organic-inorganic composite-based material including a bead type polymer additive. A content of the bead type polymer additive may range from 0.1 wt % to 2.0 wt % in 100 wt % of the protective layer 50.

The panel 1 for a home appliance may have a stacked structure. Specifically, the panel 1 for a home appliance may have the stacked structure in which the base material layer 10, the pattern layer 20, the coupling layer 40, the color layer 30, and the protective layer 50 are sequentially stacked.

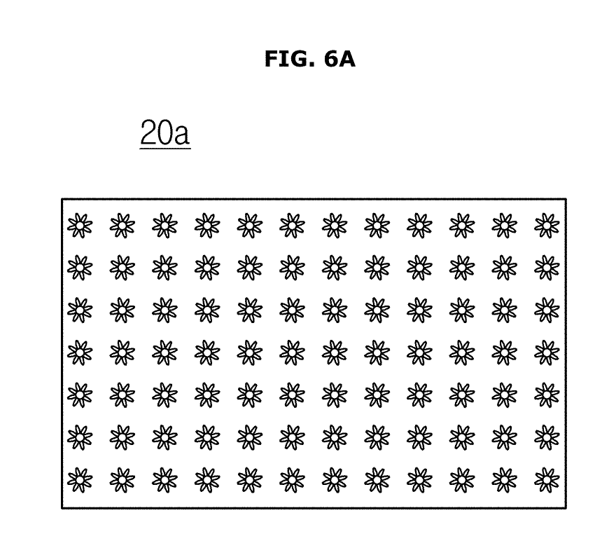

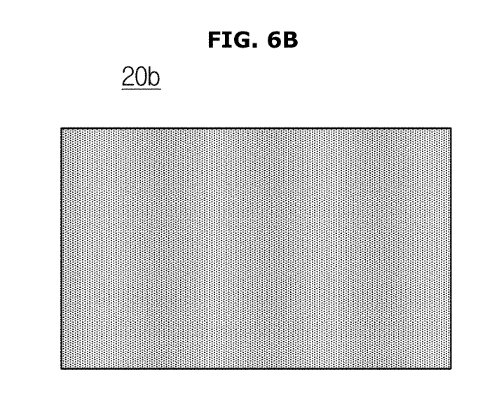

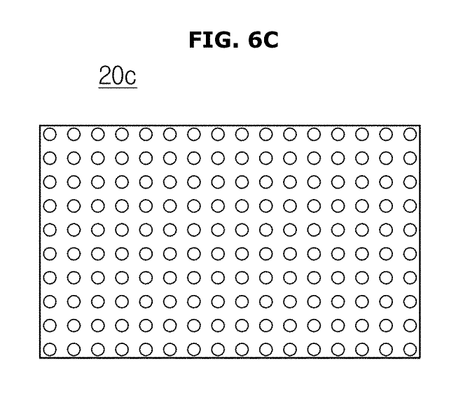

FIG. 5 is a picture showing a material of the panel for the home appliance of FIG. 1, and FIGS. 6A to 6C are views illustrating various patterns applicable to a pattern layer of the panel for a home appliance according to one embodiment of the present disclosure.

As illustrated in FIGS. 5 to 6C, the pattern layer 20 may include various patterns. For example, the pattern layer 20 may include at least one of a linear pattern, a dot pattern, and an embossing pattern

As illustrated in FIG. 5, the patterer layer 20 may include the linear pattern. The pattern layer 20 may include various linear patterns in a hair shape.

As illustrated in FIG. 6A, a pattern layer 20a may have a flower shaped pattern.

As illustrated in FIG. 6B, a pattern layer 20b may include a dot pattern.

As illustrated in FIG. 6C, a pattern layer 20c may include an embossing pattern.

The patterns applicable to the pattern layers 20, 20a, 20b, and 20c are not limited thereto, and may be variously changed.

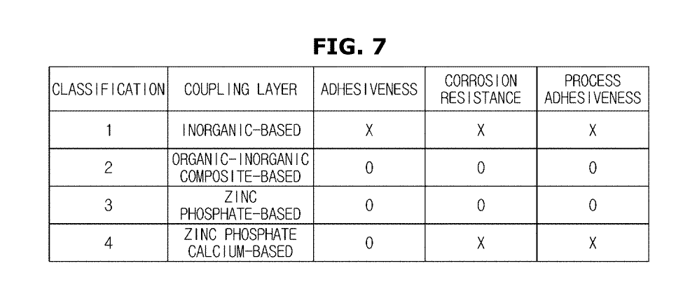

FIG. 7 is a table showing whether a coupling layer has adhesiveness, corrosion resistance, and process adhesiveness based on a component forming the coupling layer. In the table, “O” denotes the presence of adhesiveness, corrosion resistance, or process adhesiveness, and “X” denotes the absence of adhesiveness, corrosion resistance, or process adhesiveness. An adhesiveness test may be performed as follows. After a flat panel 1 for a home appliance is prepared, the panel 1 for a home appliance is taped at room temperature. Then, the tape is removed from the panel 1 for a home appliance, and a state of a surface of the panel 1 for a home appliance from which the tape is removed is checked. Here, “presence of adhesiveness” means that, when the tape is removed from the panel 1 for a home appliance, the panel 1 for a home appliance does not have a specific abnormality, and “absence of adhesiveness” means that, when the tape is removed from the panel 1 for a home appliance, cracks or a delamination occurs at the panel 1 for a home appliance. The presence of the process adhesiveness may be checked through a t-bending test. “Presence of process adhesiveness” means that, when t-bending is performed on the panel 1 for a home appliance, there is no specific abnormality, and “absence of process adhesiveness” means that, when t-bending is performed on the panel 1 for a home appliance, cracks or a delamination occurs at the panel 1 for a home appliance. The presence of corrosion resistance may be checked by scratching the panel 1 for a home appliance and spraying 5% NaCl salt water on the panel 1 for a home appliance ten times. “Presence of corrosion resistance” means that the panel 1 for a home appliance is not corroded even though the panel 1 is sprayed with salt water ten times, and “absence of corrosion resistance” means that the panel 1 for a home appliance is corroded as a result of being sprayed with salt water ten times. In a case of an “inorganic material,” the experiments are performed using silicon (Si), and here, a weight of the coupling layer 40 is mainly that of the silicon and is 100 mg/m². In a case of an “organic-inorganic composite-based material,” the experiments are performed using a titanium (Ti)/manganese (Mn) polymer, and here, the weight of the coupling layer 40 is mainly that of the titanium (Ti) and is 60 mg/m², in a case of a “zinc phosphate-based material,” the weight of the coupling layer 40 is mainly that of zinc phosphate and is in the range of 1 mg/m² to 3 mg/m². In a case of a “zinc phosphate calcium-based material,” the weight of the coupling layer 40 is mainly that of zinc phosphate calcium and is in the range of 2 mg/m² to 4 mg/m².

In the case of the coupling layer 40 formed of the “inorganic material,” it can be seen that the coupling layer 40 did not have adhesiveness, corrosion resistance, and process adhesiveness.

in the case of the coupling layer 40 formed of the “organic-inorganic composite-based material,” it can he seen that the coupling layer 40 had adhesiveness, corrosion resistance, and process adhesiveness.

In the case of the coupling layer 40 formed of the “zinc phosphate-based material,” it can be seen that the coupling layer 40 had adhesiveness, corrosion resistance, and process adhesiveness. As a result of the experiments, it can be seen that reliability of the panel 1 for a home appliance was the most excellent when the coupling layer 40 formed of the “zinc phosphate-based material” or the “organic-inorganic composite-based material” was applied thereto.

In the case of the coupling layer 40 formed of the “zinc phosphate calcium-based material,” it can be seen that the coupling layer 40 had adhesiveness but did not have corrosion resistance and process adhesiveness.

Consequently, it can be seen that the organic-inorganic composite-based material and the zinc phosphate-based material are suitable as a material forming the coupling layer 40.

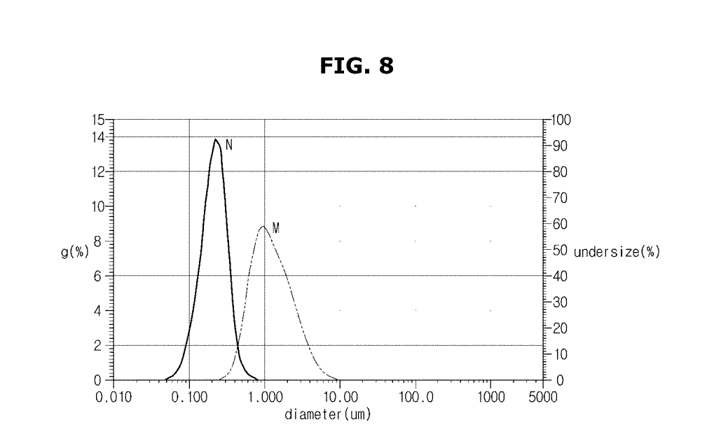

FIG. 8 is a graph showing an extent to which a black color is developed on the basis of a particle size of a pigment dispersant forming a color layer. That is, FIG. 8 is a graph showing a particle size distribution of a pigment dispersant. The horizontal axis of the graph denotes a particle size (m) of the pigment dispersant. A right vertical axis and a left vertical axis respectively denote an undersize and a q (%). Simply state, the vertical axes of the graphs denote a distribution extent of the pigment dispersant. Hereinafter, a curved line located on the left in FIG. 8 is referred to as “N,” and a curved line located on the right in FIG is referred as “M.” N shows a distribution of a pigment dispersant having a particle size in the range of more than 0 nm to 300 nm, and M shows a distribution of a pigment dispersant having a particle size in the range of 1 μm to 2 μm. N has a peak when the particle size is 220 nm, and M has a peak when the particle size is 1.5 μm.

In the graph of FIG. 8, it can be seen that N has a sharper shape than M. This may be interpreted as meaning that the pigment dispersant having the particle size in the range of more than 0 nm to 300 nm has a relatively uniform particle size distribution while the pigment dispersant having the particle size in the range of 1 μm to 2 μm has a relatively non-uniform particle size distribution.

The pigment dispersant having the particle size in the range of 1 μm to 2 μm has a gloss of 90 under an opalescence condition of 60 gloss, and has a gloss of 50 under an anti-opalescence condition of 60 gloss. However, the pigment dispersant having the particle size in the range of more than 0 nm to 300 nm has a gloss of 120 under the opalescence condition of 60 gloss and has a gloss of 80 under the anti-opalescence condition of 60 gloss.

Consequently, it can be seen that the pigment dispersant having the particle size in the range of more than 0 nm to 300 nm has a relatively uniform particle size distribution and a superior gloss.

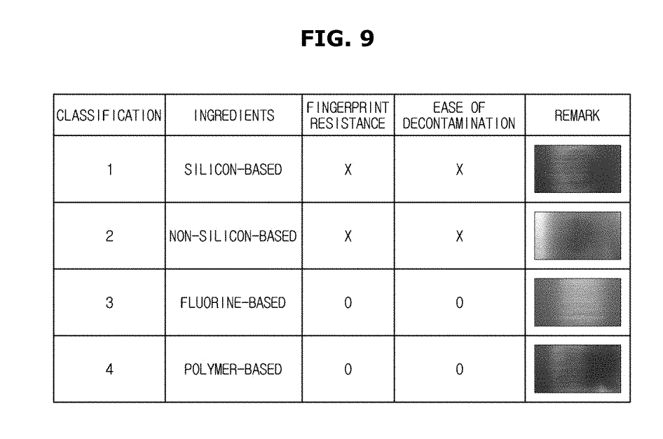

FIG. 9 is a table showing whether a protective layer has fingerprint resistance and ease of decontamination based on a kind of additive forming the protective layer. In the table, “O” denotes the presence of fingerprint resistance and ease of decontamination, and “X” denotes the absence of fingerprint resistance or ease of decontamination.

In the case of the protective layer 50 including the “silicon-based additive,” it can be seen that the protective layer 50 did not have fingerprint resistance or ease of decontamination. It can be seen that a trace estimated as a fingerprint of a user is not easily, removed from the panel 1 for a home appliance when the “protective layer 50 including the “silicon-based additive” was applied thereto.

In the case of the protective layer 50 including a “non-silicon-based additive,” it can be seen that the protective layer 50 did not have fingerprint resistance or ease of decontamination. It can be seen that a trace estimated as a fingerprint of a user is not easily removed from the panel 1 for a home appliance when the protective layer 50 including the “non-silicon-based additive” was applied thereto.

In the case of the protective layer 50 including the “fluorine-based additive,” it can be seen that the protective layer 50 had fingerprint resistance and ease of decontamination It can be seen that a trace estimated as a fingerprint did not remain on the panel 1 for a home appliance when the protective layer 50 including the “fluorine-based additive” was applied thereto

In the case of the protective layer 50 including the “polymer additive,” it can be seen that the protective layer 50 had fingerprint resistance and ease of decontamination. It can be seen that a trace estimated as a fingerprint of a user did not remain on the panel I for a home appliance when the protective layer 50 including the “polymer additive” was applied thereto.

As a result of the experiments, it can be seen that fingerprint resistance and ease of decontamination of the panel 1 for a home appliance were most excellent when the protective layer 50 including the “fluorine-based additive” or the protective layer 50 including the “polymer additive” was applied thereto.

As is apparent from the above description, firm coupling of a base material layer and a color layer can be realized by applying a coupling layer including at least one of an organic-inorganic composite-based material and a zinc phosphate-based material to the panel.

A pattern layer and a color layer can be clearly expressed by using a pigment dispersant having a particle size of 500 nm or less.

Fingerprint resistance and ease of decontamination of a panel for a home appliance may be improved by applying a protective layer including at least one of a water-soluble material, an oil-based material, and an organic-inorganic composite-based material including a fluorine-based additive to the panel.

Fingerprint resistance and ease of decontamination of a panel for a home appliance may be maximized by applying a protective layer including at least one of a water-soluble material, an oil-based material, and an organic-inorganic composite-based material including a bead type polymer additive to the panel.

Although a few embodiments of the present invention have been shown and described above, the invention is not limited to the aforementioned specific exemplary embodiments. Those skilled in the art may variously modify the invention without departing from the gist of the invention claimed in the appended claims.

Although the present disclosure has been described with an exemplary embodiment, various changes and modifications may be suggested to one skilled in the art. It is intended that the present disclosure encompass such changes and modifications as fall within the scope of the appended

What is claimed is:

1. A panel for a home appliance provided to form an exterior of a home appliance, the panel comprising:
a base material layer;
a pattern layer formed on the base material layer;
a color layer disposed on the pattern layer to develop a color;
a coupling layer applied on the pattern layer to couple the base material layer and the color layer; and
a protective layer disposed on the color layer such that contamination is easily removed therefrom.

2. The panel of claim 1, wherein the base material layer includes a stainless steel.

3. The panel of claim 1, wherein the color layer includes a black paint to develop a black color.

4. The panel of claim 1, wherein the pattern layer includes at least one of a linear pattern, a dot pattern, and an embossing pattern.

5. The panel of claim 1, wherein the coupling layer includes at least one of an organic-inorganic composite-based material and a zinc phosphate-based material.

6. The panel of claim 3, wherein the black paint includes a pigment dispersant, wherein 90% or more of the pigment dispersant has a particle size in a range of 60 nm to 350 nm.

7. The panel of claim 6, wherein a content of the pigment dispersant ranges from 8.0 wt % to 15.0 wt % in 100 wt % of the black paint.

8. The panel of claim 6, wherein:
the black paint further includes a resin including at least one of an epoxy resin and an acryl resin; and
a content of the resin ranges from 30 wt % to 50 wt % in 100 wt % of the black paint.

9. The panel of claim 1, wherein the protective layer includes at least one of a water-soluble material, an oil-based material, and an organic-inorganic composite-based maerial including a fluorine-based additive.

10. The panel of claim 9, wherein a content of the fluorine-based additive ranges from 0.1 wt % to 2.0 wt % in 100 wt % of the protective layer.

11. The panel of claim 1, wherein the protective layer includes at least one of a water-soluble material, an oil-based material, and an organic-inorganic composite-based material including a bead type polymer additive.

12. The panel of claim 11, wherein a content of the bead type polymer additive ranges from 0.1 wt % to 2.0 wt % in 100 wt % of the protective layer.

13. A home appliance comprising:
a main body provided to form an exterior of the home appliance; and
a panel for a home appliance configured to form at least one surface of outer surfaces of the main body, wherein the panel for a home appliance includes:
a base material layer formed of a metal material;
a pattern layer formed on the base material layer;
a color layer disposed on the pattern layer to develop a color;
a coupling layer applied on the pattern layer to couple the base material layer and the color layer; and
a protective layer disposed on the color layer such that contamination is easily removed therefrom.

14. The home appliance of claim 13, wherein the color layer includes a black paint to develop a black color.

15. The home appliance of claim 13, wherein the coupling layer includes at least one of an organic-inorganic composite-based material and a zinc phosphate-based material.

16. The home appliance of claim 14, ‘herein the black paint includes:
a pigment dispersant; and
a resin including at least one of an epoxy resin and an acryl resin,
wherein 90% or more of the pigment dispersant has a particle size in a range of 60 nm to 350 nm.

17. The home appliance of claim 13, wherein the protective layer includes at least one of a fluorine-based additive and a polymer additive,

18. A home appliance comprising:
a cabinet;
a door rotatably installed at the cabinet and configured to form an exterior of the home appliance together with the cabinet; and
a panel for a home appliance provided to form an outer surface of the door,
wherein the panel for a home appliance includes:
a base material layer formed of a metal material;
a pattern layer formed on the base material layer;
a color layer disposed on the pattern layer to develop a color;
a coupling layer applied on the pattern layer to couple the base material layer and the color layer; and
a protective layer disposed on the color layer such that contamination is easily removed therefrom and including at least one of a fluorine-based additive and a polymer additive.
